(19) United States
(12) Patent Application Publication
(10) Pub. No.: US 2009/0052693 A1
(43) Pub. Date: Feb. 26, 2009

(54) Sound Reproducing Apparatus

(75) Inventors: Kazuhisa Kotegawa, Osaka (JP); Shinnosuke Nagasawa, Osaka (JP)

Correspondence Address: RATNERPRESTIA, P.O. BOX 980, VALLEY FORGE, PA, 19482, US

(73) Assignee: PANASONIC CORPORATION, Osaka (JP)

(21) Appl. No.: 11/913,725

(22) PCT Filed: Jun. 8, 2006
(86) PCT No.: PCT/JP2006/311508

§ 371 Date: Nov. 6, 2007

(30) Foreign Application Priority Data
Jun. 15, 2005 (JP) 2005-174581

(51) Int. Cl. H03G 5/00

(52) U.S. Cl. 381/98

(57) ABSTRACT

A sound reproducing apparatus is structured to use a first dividing circuit and a determining circuit to analyze a frequency characteristic of an inputted signal and to output a signal adjusted by a first adjusting circuit to have a prescribed frequency characteristic by a switching by a switch circuit. Thus, when signals having different frequency characteristics are inputted, frequency characteristics of the input signals can be automatically adjusted without using an external signal and channels having different frequency characteristics can be reproduced by a single system to provide good speaker-reproduced sound.

### TECHNICAL FIELD

The present invention relates to a sound reproducing apparatus that can reproduce channels in which sounds having different frequency characteristics are recorded (e.g., woofer channels for CD and DVD) under a single acoustic field environment and with a good sound quality.

### BACKGROUND ART

Japanese Patent Unexamined Publication No. 2001-112098 discloses a technique for a conventional sound reproducing apparatus. When this technique is used to reproduce a two channel source such as CD and a multi channel source including a woofer channel such as DVD in which only a low frequency is recorded under a single acoustic field reproducing environment, a switch is used to provide a switching between a two channel signal line and a multi channel signal line.

However, a sound reproducing apparatus having the conventional structure as described above has required an external signal for making distinction between a two channel and a multi channel when a switching between signals is performed.

### SUMMARY OF THE INVENTION

A sound reproducing apparatus includes: a music signal source; a dividing circuit formed of at least one filter for dividing the music signal source into prescribed bands; a determining circuit for determining, based on an output from the dividing circuit, a frequency included in the music signal source; an adjusting circuit formed of at least one filter for adjusting the music signal source to have a prescribed frequency characteristic; and a switch circuit for switching an output of the adjusting circuit. An output from the determining circuit is used to control the switch circuit to output a signal adjusted to have a prescribed frequency characteristic.

The structure as described above allows, when channels having different frequency characteristics (e.g., a two channel source (e.g., CD) and a multi channel source (e.g., DVD)) are reproduced, the frequency characteristics of the music signal source themselves can be used to switch signal lines to adjust the multi channel source to have a prescribed frequency characteristic. As a result, when channels having different frequency characteristics (e.g., a woofer channel of DVD and CD) are reproduced by a single system, good speaker-reproduced sound can be realized.

### BRIEF DESCRIPTION OF THE DRAWINGS

FIG. 1 is a block diagram illustrating a sound reproducing apparatus in Embodiment 1 of the present invention.

FIG. 2 is a frequency characteristic diagram illustrating an input signal of a music signal source in Embodiment 1 of the present invention.

FIG. 3 is a frequency characteristic diagram illustrating an output signal of the first adjusting circuit in Embodiment 1 of the present invention.

FIG. 4 is a frequency characteristic diagram illustrating another input signal of the music signal source in Embodiment 1 of the present invention.

FIG. 5 is a block diagram illustrating a sound reproducing apparatus in Embodiment 2 of the present invention.

FIG. 6 is a block diagram illustrating a sound reproducing apparatus in Embodiment 3 of the present invention.

### REFERENCE MARKS IN THE DRAWINGS

11 Music signal source

12 First dividing circuit

13 Second dividing circuit

14 First adjusting circuit

15 Second adjusting circuit

16 Determining circuit

17 Switch circuit

20 Output signal

### DETAILED DESCRIPTION OF PREFERRED EMBODIMENTS

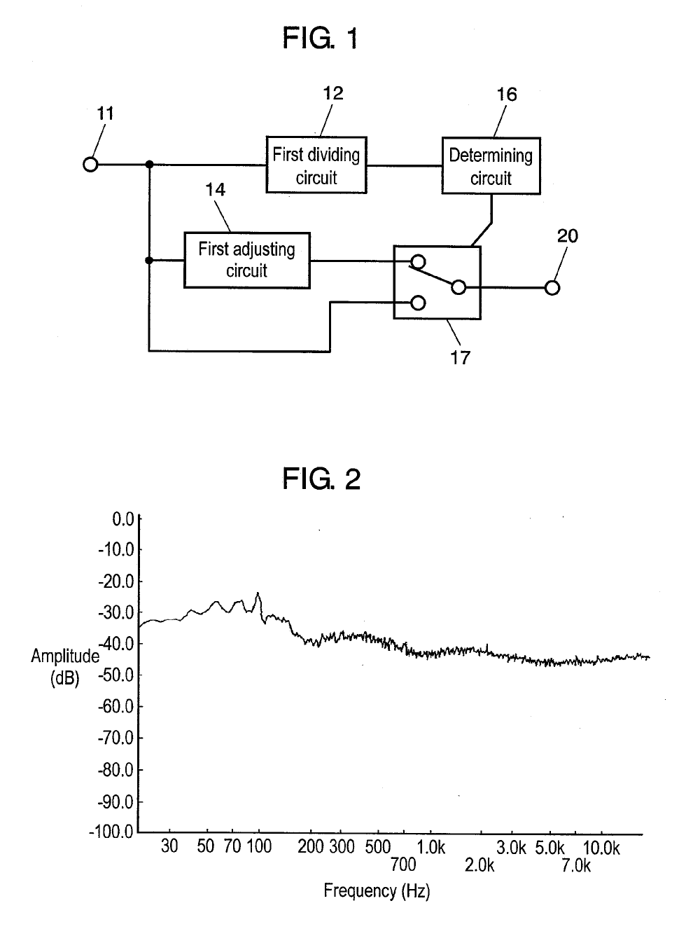

Hereinafter, an embodiment of the present invention will be described with reference to FIG. 1 to FIG. 6.

### Embodiment 1

FIG. 1 is a block diagram illustrating a sound reproducing apparatus in Embodiment 1 of the present invention. First, with reference to FIG. 1, the structure of the sound reproducing apparatus in Embodiment 1 will be described.

As shown in FIG. 1, a sound reproducing apparatus in Embodiment 1 includes music signal source 11, first dividing circuit 12, and first adjusting circuit 14. Music signal source 11 is an input signal. First dividing circuit 12 is formed of a low-pass filter, a high-pass filter, a band-pass filter or the like and is formed of at least one filter for dividing music signal source 11 into prescribed bands. First adjusting circuit 14 is formed of at least one filter for adjusting music signal source 11 to have a prescribed frequency characteristic (e.g., low-pass filter, high-pass filter, band-pass filter). The sound reproducing apparatus in Embodiment 1 also includes determining circuit 16 and switch circuit 17 Determining circuit 16 uses an absolute value circuit and a comparator or a wind comparator or the like to determine whether an input signal includes a prescribed band signal of a certain level or higher with regards to an output signal of first dividing circuit 12 to output a signal and determines, based on an output from first dividing circuit 12, a frequency included in the music signal source. Switch circuit 17 uses the output signal of determining circuit 16 to switch whether first adjusting circuit 14 is used as output signal 20 or output signal 20 is directly used as music signal source 11.

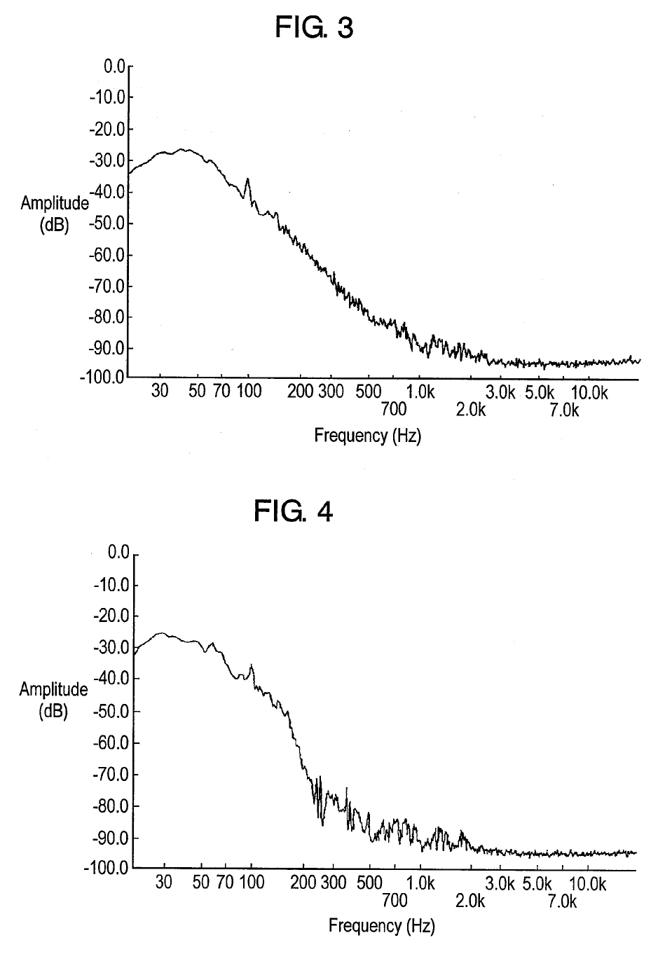

Next, an operation of the sound reproducing apparatus in Embodiment 1 having the structure as described above will be described with reference to FIG. 2, FIG. 3, and FIG. 4. FIG. 2 is a frequency characteristic diagram of an input signal of the music signal source in Embodiment 1. FIG. 3 is a frequency characteristic diagram of an output signal of the first adjusting circuit in Embodiment 1. FIG. 4 is a frequency characteristic diagram of another input signal of the music signal source in Embodiment 1.

When the sound reproducing apparatus in Embodiment 1 receives a signal as music signal source 11 including a high frequency component of a certain level or more as shown in FIG. 2 for example, first dividing circuit 12 formed of a high-pass filter or the like extracts only a high frequency component from music signal source 11. Then, an absolute value circuit and a comparator or a wind comparator or the like are used to detect the level of the signal of the broadband component to subsequently allow determining circuit 16 to determine whether the level is equal to or higher than a certain level or not. In this manner, it is determined that a mixed signal of a two channel source for CD for example is used as a woofer signal. Then, first adjusting circuit 14 adjusts the frequency characteristic of music signal source 11 and an output of first adjusting circuit 14 as shown in FIG. 3 is used as an output signal. When a signal not including a high frequency component as shown in FIG. 4 is inputted as music signal source 11, it is determined in a similar manner that a woofer signal of a multi channel source for DVD for example is used. Then, music signal source 11 is directly outputted. As described above, by performing the adjustment as shown in FIG. 3 and FIG. 4 to provide substantially equal frequency characteristics, the sound reproducing apparatus in Embodiment 1 can favorably reproduce even a source in which different frequency characteristics are recorded such as a two channel source and a multi channel source.

Although Embodiment 1 has used a high-pass filter as first dividing circuit 12, a similar control also can be performed by another structure such as a combination of a band-pass filter and another filter so that music signal source 11 can be divided into prescribed bands.

### Embodiment 2

A sound reproducing apparatus in Embodiment 2 is characterized in that Embodiment 1 of the present invention is added with a second dividing circuit and a plurality of dividing circuits are used to improve an accuracy at which a frequency characteristic is determined by the determining circuit.

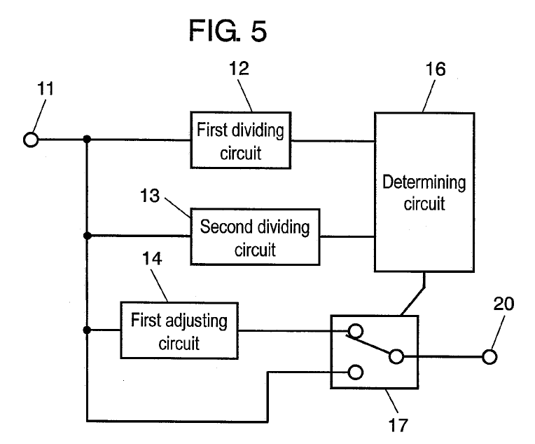

FIG. 5 is a block diagram illustrating a sound reproducing apparatus in Embodiment 2 of the present invention. First, with reference to FIG. 5, the structure of the sound reproducing apparatus in Embodiment 2 will be described.

As shown in FIG. 5, the sound reproducing apparatus in Embodiment 2 includes: music signal source 11, first dividing circuit 12, second dividing circuit 13, and first adjusting circuit 14. Music signal source 11 is an input signal. First dividing circuit 12 is formed of at least one filter (e.g., low-pass filter, high-pass filter, band-pass filter) and divides an input signal into prescribed bands. Second dividing circuit 13 is formed of at least one filter (e.g., band-pass filter) and divides an input signal into prescribed bands. First adjusting circuit 14 is formed of a low-pass filter, a high-pass filter, and a band-pass filter for example and adjusts music signal source 11 to have a prescribed frequency characteristic. The sound reproducing apparatus in Embodiment 2 also includes determining circuit 16 and switch circuit 17. Determining circuit 16 determines, with regards to output signals from first dividing circuit 12 and second dividing circuit 13, whether the input signals include a signal having a prescribed band or not by using an absolute value circuit and a comparator or a wind comparator or the like to output a signal. Switch circuit 17 uses the output signal from determining circuit 16 to switch whether first adjusting circuit 14 is used as output signal 20 or music signal source 11 is directly used as output signal 20.

Next, the operation of the sound reproducing apparatus in Embodiment 2 having the structure as described above will be described.

The sound reproducing apparatus in Embodiment 2 uses the structure having a plurality of dividing circuits so that first dividing circuit 12 uses a low-pass filter for extracting only a low frequency and second dividing circuit 13 uses a high-pass filter for extracting only a high frequency for example. Then, signal levels of frequency components as output results extracted by first dividing circuit 12 and second dividing circuit 13 are determined by determining circuit 16 using an absolute value circuit and a comparator or a wind comparator with regards to whether the signal levels are equal to or higher than a certain level. In this manner, only when music signal source 11 as shown in FIG. 2 includes both of a low frequency and a high frequency, the music signal as shown in FIG. 3 is outputted that is subjected to a signal processing by first adjusting circuit 14 to provide a prescribed frequency characteristic. When music signal source 11 as shown in FIG. 2 includes only a low frequency as shown in FIG. 4, the signal processing is skipped and music signal source 11 is directly outputted. Therefore, an adjustment as shown in FIG. 3 and FIG. 4 to provide substantially equal frequency characteristics can be performed to favorably reproduce even a source in which different frequency characteristics (e.g., a two channel source and a multi channel source) are recorded for example. In this manner, a sound reproducing apparatus can be provided that can allow determining circuit 16 to determine a frequency characteristic with a higher accuracy to realize a favorable sound reproduction.

### Embodiment 3

A sound reproducing apparatus in Embodiment 3 is characterized in that Embodiment 2 of the present invention is added with a second adjusting circuit to use a plurality of adjusting circuits.

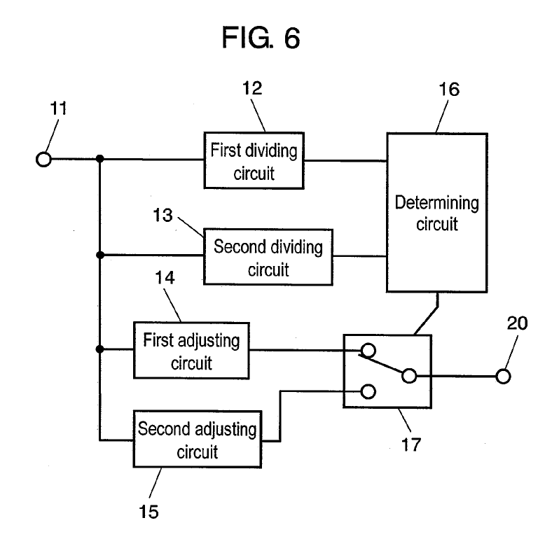

FIG. 6 is a block diagram illustrating a sound reproducing apparatus in Embodiment 3 of the present invention. First, the structure of the sound reproducing apparatus in Embodiment 3 will be described with reference to FIG. 6.

As shown in FIG. 6, the sound reproducing apparatus Embodiment 3 includes music signal source 11, first dividing circuit 12, second dividing circuit 13, first adjusting circuit 14, and second adjusting circuit 15. Music signal source 11 is an input signal. First dividing circuit 12 is formed of a low-pass filter, a high-pass filter, or a band-pass filter or the like and divides an input signal into prescribed bands. Second dividing circuit 13 is formed of a low-pass filter, a high-pass filter, or a band-pass filter or the like and divides an input signal into prescribed bands. First adjusting circuit 14 is formed of a low-pass filter or a band-pass filter or the like and adjusts music signal source 11 to have a prescribed frequency characteristic. Second adjusting circuit 15 is formed of a low-pass filter or a band-pass filter or the like and adjusts music signal source 11 to have a prescribed frequency characteristic. The sound reproducing apparatus Embodiment 3 also includes determining circuit 16 and switch circuit 17. Determining circuit 16 determines whether uses an absolute value circuit and a comparator or a wind comparator or the like to determine whether an input signal includes a prescribed band signal of a certain level or higher with regards to output signals from first dividing circuit 12 and second dividing circuit 13 to output a signal. Switch circuit 17 uses an output signal of determining circuit 16 to switch whether first adjusting circuit 14 is used as output signal 20 or second adjusting circuit 15 is used as output signal 20.

Next, the operation of the sound reproducing apparatus in Embodiment 3 having the structure as described above will be described.

The sound reproducing apparatus in Embodiment 3 can perform a control by using the similar determination results as in Embodiments 1 and 2. The sound reproducing apparatus in Embodiment 3 also can subject, when music signal source 11 includes only a low frequency component, the signal to a signal processing in which the signal is provided with an optimal frequency characteristic. The sound reproducing apparatus in Embodiment 3 also can subject, when music signal source 11 includes both of a low frequency component and a high frequency component, the signal to a signal processing for specific optimization in which the signal is provided with an optimal frequency characteristic.

For example, when music signal source 11 includes only a low frequency component for example, the signal processing in Embodiment 3 uses first adjusting circuit 14 to reduce the bandwidth of the signal so that only a signal having a further lower frequency component can be used. When music signal source 11 includes both of a low frequency component and a high frequency component, second adjusting circuit 15 can subject the signal to a signal processing for reducing the bandwidth to a similar bandwidth. In this manner, frequency characteristics of first adjusting circuit 14 and second adjusting circuit 15 can be respectively adjusted so as to have a prescribed frequency characteristic and are appropriately switched, thus realizing a favorable sound reproduction.

Although Embodiment 3 includes a plurality of dividing circuits, one dividing circuit also may be used. The reason is that the first dividing circuit and the determining circuit can be used to determine a frequency component included in an inputted music signal source as shown in Embodiment 1 and thus a plurality of adjusting circuits can be used to provide the same effect.

The respective structures of Embodiments 1, 2, and 3 can be provided by hardware or a digital signal processing by software or a combination thereof to perform the same control.

### INDUSTRIAL APPLICABILITY

According to the present invention, sources in which different frequency characteristics are recorded in specific channels such as DVD and CD can be reproduced with a good sound quality. Thus, the present invention can be advantageously used for a sound reproducing apparatus that can reproduce multiple channels.

1. A sound reproducing apparatus comprising:
a music signal source;
a dividing circuit formed of at least one filter for dividing the music signal source into prescribed bands;
a determining circuit for determining a frequency included in the music signal source based on an output from the dividing circuit;
an adjusting circuit formed of at least one filter for adjusting a frequency characteristic of the music signal source to a prescribed frequency characteristic; and
wherein a signal adjusted to a prescribed frequency characteristic is outputted by controlling the switch circuit using an output from the determining circuit.

2. The sound reproducing apparatus according to claim 1, wherein
the sound reproducing apparatus includes the plurality of dividing circuits, and
the determining circuit receives signals having prescribed bands of the music signal source outputted from the plurality of dividing circuits.

3. The sound reproducing apparatus according to claim 1, wherein
the sound reproducing apparatus includes the plurality of adjusting circuits.

4. The sound reproducing apparatus according to claim 1, wherein
the sound reproducing apparatus includes the plurality of adjusting circuits and the plurality of dividing circuits, and
the determining circuit receives signals having prescribed bands of the music signal source outputted from the plurality of dividing circuits.
